(19) United States
(12) Patent Application Publication
(10) Pub. No.: US 2014/0077350 A1
(43) Pub. Date: Mar. 20, 2014

(54) SEMICONDUCTOR DEVICE, METHOD FOR MANUFACTURING SEMICONDUCTOR DEVICE, AND ELECTRONIC DEVICE

(71) Applicant: Sony Corporation, Tokyo (JP)

(72) Inventor: Hirohisa Yasukawa, Kanagawa (JP)

(73) Assignee: Sony Corporation, Tokyo (JP)

(21) Appl. No.: 14/025,543

(22) Filed: Sep. 12, 2013

(30) Foreign Application Priority Data
Sep. 20, 2012 (JP) 2012-207434

(51) Int. Cl. H01L 23/34; H01L 21/48

(52) U.S. Cl. CPC H01L 23/34; H01L 21/4871
USPC 257/692; 438/122

(57) ABSTRACT

Provided is a semiconductor device including a wiring board including a plurality of alternately stacked insulating layers and wiring layers, the wiring layers being connected to each other by via-plugs, a semiconductor chip mounted on the wiring board, a heat-dissipating member that is disposed on a side opposite to the wiring board with the semiconductor chip sandwiched between the wiring board and the heat-dissipating member, and dissipates heat generated in the semiconductor chip, a sealing resin layer that is bonded to the wiring board and the heat-dissipating member between the wiring board and the heat-dissipating member, and seals the semiconductor chip from an outer periphery side, and a heat-conducting material that is bonded to the semiconductor chip and the heat-dissipating member between the semiconductor chip and the heat-dissipating member inside the sealing resin layer and conducts heat generated in the semiconductor chip to the heat-dissipating member.

### CROSS REFERENCES TO RELATED APPLICATIONS

The present application claims priority to Japanese Priority Patent Application JP 2012-207434 filed in the Japan Patent Office on Sep. 20, 2012, the entire content of which is hereby incorporated by reference.

### BACKGROUND

The present application relates to a technical field of a semiconductor device, a method for manufacturing the semiconductor device, and an electronic device. Specifically, the present application relates to a technical field to secure excellent bondability of a heat-conducting material to a semiconductor chip by forming, in a heat-dissipating member that dissipates heat generated in the semiconductor chip, a through hole to the heat-conducting material, and to secure an excellent heat dissipation property of heat generated in the semiconductor chip.

In recent years, the speed and functions of semiconductor chips, such as ICs (integrated circuits) and LSIs (large scale integrations), used as microprocessors and the like in computers, cell phones, and the like have been made higher and higher. In response to this, the number of electrodes (terminals) tends to be increased, and pitches between the electrodes tend to be decreased. Usually, a large number of electrodes are provided in an array form at the bottom surface of the semiconductor chip.

Terminal portions of such a semiconductor chip have a large pitch difference from connection terminals formed over a circuit board called motherboard. Therefore, it is difficult to mount the semiconductor chip on the motherboard.

Accordingly, in order to connect the semiconductor chip to the motherboard, a wiring board including a plurality of insulating layers and a plurality of wiring layers is formed, the wiring board is mounted on (connected to) the motherboard, and the semiconductor chip is mounted on the wiring board, so that the semiconductor chip are connected to the motherboard via the wiring board. With the wiring board, the semiconductor chip, and the like, a structure body called semiconductor package (semiconductor device) is formed.

Further, as electronic devices become downsized, have higher functions, and operate at higher speed, semiconductor devices incorporating semiconductor chips for these electronic devices are demanded to be more downsized, operate at even higher speed, and have even higher density.

However, when the semiconductor devices are downsized, operate at higher speed, and have higher density, the power consumption is increased and the amount of heat generated per unit volume tends to increase. Therefore, a further increase in the efficiency and the stability of heat dissipation of the semiconductor devices are demanded.

As a mounting structure of a semiconductor chip in the past, a flipchip mount structure is known in which a surface on which external electrodes of the semiconductor chip are provided faces downward.

As a technique to dissipate heat of the semiconductor chip that is flipchip-mounted as described above, there is a technique to dissipate heat generated in the semiconductor chip by disposing a heat-dissipating member over a thermal interface material (TIM) used as a heat-conducting material, the TIM being formed on a surface opposite to a surface on which the external electrodes of the semiconductor chip are provided (see FIG. 8 in JP 2001-257288A, for example). As the heat-conducting material, for example, an alumina paste, a silver paste, or the like is used.

Specifically, in the semiconductor device, the heat-dissipating member is disposed so as to cover, from the above, the semiconductor chip mounted on the wiring board, and the heat-conducting material is provided between a lower surface of the heat-dissipating member and a top surface of the semiconductor chip. Therefore, the heat-conducting material is bonded to the top surface of the semiconductor chip and the lower surface of the heat-dissipating member, and heat generated in the semiconductor chip is conducted to the heat-dissipating member by the heat-conducting material and dissipated from the heat-dissipating member.

Further, as a technique to fix the heat-dissipating member to the semiconductor chip, a method to fix the heat-dissipating member and the wiring board with an adhesive resin is known (see FIG. 1 in JP 2007-184351A, for example).

Specifically, a sealing resin layer is provided in an outer periphery portion of the wiring board, i.e., on an outer periphery side of the semiconductor chip, an outer periphery portion of the heat-dissipating member is bonded to the sealing resin layer with the adhesive resin, and the heat-dissipating member is fixed to the wiring board. Therefore, the semiconductor chip is sealed from the outer periphery side by the sealing resin layer, and also the heat-dissipating member is fixed to the semiconductor chip.

Further, an underfill resin material is provided inside the sealing resin layer, and a space between the semiconductor chip and the wiring board is sealed with the underfill resin material.

### SUMMARY

By the way, in the above-described semiconductor device, although solder balls called ball grid array (BGA) are provided below a lower surface of the wiring board and the wiring board is connected to a circuit board by the solder balls, the entire semiconductor device may warp at the time of reflow of the solder balls and the like.

Such a warp is mainly generated by a difference in the coefficient of thermal expansion between the semiconductor chip and the wiring board or a difference in the coefficient of thermal expansion between the semiconductor chip and the underfill resin material. Specifically, the warp is generated because the coefficient of thermal expansion of the wiring board or the underfill resin material is higher than that of the semiconductor chip.

A state of the warp generated when reflow is performed in the semiconductor device will be described below (see FIG. 17 and FIG. 18).

A semiconductor device a includes a wiring board b, a semiconductor chip c, and a heat-dissipating member d.

Below a lower surface of the wiring board b, solder balls (BGA) e, e, . . . for connection to an unillustrated circuit board are provided.

The semiconductor chip c is mounted on a top surface of the wiring board b, and a space between the wiring board b and the semiconductor chip c is sealed with an underfill resin material f.

The heat-dissipating member d is bonded to the semiconductor chip c with the heat-conducting material (TIM) g interposed therebetween, the TIM g being bonded to a top surface of the semiconductor chip c.

A sealing resin layer h is provided in an outer periphery portion of the wiring board b, and the heat-dissipating member d is fixed to the sealing resin layer h. Therefore, the semiconductor chip c is sealed from an outer periphery side with the sealing resin layer h.

FIG. 17 is a view schematically illustrating a state of a warp during the reflow in the semiconductor device a (at high temperatures).

During the reflow, a warp is generated by a difference in the coefficient of thermal expansion between the semiconductor chip c and the wiring board b, a difference in the coefficient of thermal expansion between the semiconductor chip c and the underfill resin material f, and the like such that the wiring board b is curved to project downward. At this time, in the semiconductor device a, a force A to a direction (pulling direction) in which the semiconductor chip c and the heat-conducting material g are to be separated from each other is added.

On the other hand, FIG. 18 is a view schematically illustrating a state of a warp at the time of reflow cooling of the semiconductor device a (at room temperature).

At the time of the reflow cooling, a warp is generated by a difference in the coefficient of thermal expansion between the semiconductor chip c and the wiring board b, a difference in the coefficient of thermal expansion between the semiconductor chip c and the underfill resin material f, and the like such that the wiring board b is curved to project upward. At this time, in the semiconductor device a, a force B to a direction (compressing direction) in which the semiconductor chip c and the heat-conducting material g are pushed to each other is added.

When any of the above warps is generated in the semiconductor device a, the heat-conducting material g that connects the heat-dissipating member d and the semiconductor chip c might be separated from the semiconductor chip c. When the heat-conducting material g is separated from the semiconductor chip c, heat generated in the semiconductor chip c fails to be sufficiently conducted to the heat-dissipating member d, so that a heat dissipation performance is degraded and reliability of operation of the semiconductor device a is decreased.

Accordingly, according to the semiconductor device, the method for manufacturing the semiconductor device, and the electronic device according to embodiments of the present application, it is desirable to overcome at least one of the above-described problems, to secure excellent bondability of a heat-conducting material to a semiconductor chip, and to secure an excellent heat dissipation property of heat generated in the semiconductor chip.

Firstly, in order to solve at least one of the above-described problems, there is provided a semiconductor device including a wiring board including a plurality of alternately stacked insulating layers and wiring layers, the wiring layers being connected to each other by via-plugs, a semiconductor chip mounted on the wiring board, a heat-dissipating member that is disposed on a side opposite to the wiring board with the semiconductor chip sandwiched between the wiring board and the heat-dissipating member, and dissipates heat generated in the semiconductor chip, a sealing resin layer that is bonded to the wiring board and the heat-dissipating member between the wiring board and the heat-dissipating member, and seals the semiconductor chip from an outer periphery side, and a heat-conducting material that is bonded to the semiconductor chip and the heat-dissipating member between the semiconductor chip and the heat-dissipating member inside the sealing resin layer and conducts heat generated in the semiconductor chip to the heat-dissipating member. A through hole to the heat-conducting material is formed in the heat-dissipating member.

Secondly, in the above-described semiconductor device, it is desirable that a terminal portion of the through hole on a side opposite to the heat-conducting material is formed as a taper portion in which a diameter becomes larger as the terminal portion is farther away from the heat-conducting material.

By forming the taper portion such that the diameter becomes larger as the terminal portion of the through hole on the side opposite to the heat-conducting material side becomes farther from the heat-conducting material, the heat-conducting material can be easily injected to the through hole.

Thirdly, in the above-described semiconductor device, it is desirable that a terminal portion of the through hole on a heat-conducting material side is formed as a taper portion in which a diameter becomes larger as the terminal portion is closer to the heat-conducting material.

By forming the taper portion such that the diameter becomes larger as the terminal portion of the through hole on the side of the heat-conducting material becomes closer to the heat-conducting material, the bonding strength of the heat-conducting material to the heat-dissipating member is increased.

Fourthly, in the above-described semiconductor device, it is desirable that it is checked whether the heat-conducting material is separated from the semiconductor chip.

By checking whether the heat-conducting material is separated from the semiconductor chip, it is reliably decided whether the heat-conducting material is separated from the semiconductor chip.

In order to solve at least one of the above-described problems, there is provided a method for manufacturing a semiconductor device, the method including forming a wiring board including a plurality of alternately stacked insulating layers and wiring layers, the wiring layers being connected to each other by via-plugs, mounting a semiconductor chip on the wiring board, forming a sealing resin layer that is bonded to the wiring board and seals the semiconductor chip from an outer periphery side, attaching, to the semiconductor chip, a heat-dissipating member including a through hole to a heat-conducting material bonded to the semiconductor chip, and checking whether the heat-conducting material is separated from the semiconductor chip.

Accordingly, in the method for manufacturing the semiconductor device, it becomes possible to inject the heat-conducting material from the though hole of the heat-dissipating member.

In order to solve at least one of the above-described problems, there is provided an electronic device including a circuit board disposed inside an external housing, and a semiconductor device connected to a predetermined circuit in the circuit board. The semiconductor device includes a wiring board including a plurality of alternately stacked insulating layers and wiring layers, the wiring layers being connected to each other by via-plugs, a semiconductor chip mounted on the wiring board, a heat-dissipating member that is disposed on a side opposite to the wiring board with the semiconductor chip sandwiched between the wiring board and the heat-dissipating member, and dissipates heat generated in the semiconductor chip, a sealing resin layer that is bonded to the wiring board and the heat-dissipating member between the wiring board and the heat-dissipating member, and seals the semiconductor chip from an outer periphery side, and a heat-conducting material that is bonded to the semiconductor chip and the heat-dissipating member between the semiconductor chip and the heat-dissipating member inside the sealing resin layer and conducts heat generated in the semiconductor chip to the heat-dissipating member. A through hole to the heat-conducting material is formed in the heat-dissipating member.

Accordingly, in the electronic device, it becomes possible to inject the heat-conducting material from the though hole of the heat-dissipating member.

According to an embodiment of the present application, there is provided a semiconductor device including a wiring board including a plurality of alternately stacked insulating layers and wiring layers, the wiring layers being connected to each other by via-plugs, a semiconductor chip mounted on the wiring board, a heat-dissipating member that is disposed on a side opposite to the wiring board with the semiconductor chip sandwiched between the wiring board and the heat-dissipating member, and dissipates heat generated in the semiconductor chip, a sealing resin layer that is bonded to the wiring board and the heat-dissipating member between the wiring board and the heat-dissipating member, and seals the semiconductor chip from an outer periphery side, and a heat-conducting material that is bonded to the semiconductor chip and the heat-dissipating member between the semiconductor chip and the heat-dissipating member inside the sealing resin layer and conducts heat generated in the semiconductor chip to the heat-dissipating member. A through hole to the heat-conducting material is formed in the heat-dissipating member.

Accordingly, when a warp is generated in the semiconductor device and the heat-conducting material is separated from the semiconductor chip, it is possible to repair the separation by injecting the heat-conducting material from the through hole, to secure excellent bondability of the heat-conducting material to the semiconductor chip, and to secure an excellent heat dissipation property of heat generated in the semiconductor chip.

According to another embodiment of the present application, a terminal portion of the through hole on a side opposite to the heat-conducting material is formed as a taper portion in which a diameter becomes larger as the terminal portion is farther away from the heat-conducting material.

Accordingly, the heat-conducting material is easily injected to the through hole, and the efficiency of the injection can be increased.

According to another embodiment of the present application, a terminal portion of the through hole on a heat-conducting material side is formed as a taper portion in which a diameter becomes larger as the terminal portion is closer to the heat-conducting material.

Accordingly, it is possible to increase the bonding strength of the heat-conducting material to the heat-dissipating member, to secure an excellent conductivity of heat to the heat-dissipating member from the heat-conducting material, and to increase the heat dissipation performance.

According to another embodiment of the present application, it is checked whether the heat-conducting material is separated from the semiconductor chip.

Accordingly, it is possible to reliably decide whether the heat-conducting material is separated from the semiconductor chip, and by injecting the heat-conducting material from the through hole only in a case of necessity, it is possible to increase the manufacturing efficiency of the semiconductor device.

According to another embodiment of the present application, there is provided a method for manufacturing a semiconductor device, the method including forming a wiring board including a plurality of alternately stacked insulating layers and wiring layers, the wiring layers being connected to each other by via-plugs, mounting a semiconductor chip on the wiring board, forming a sealing resin layer that is bonded to the wiring board and seals the semiconductor chip from an outer periphery side, attaching, to the semiconductor chip, a heat-dissipating member including a through hole to a heat-conducting material bonded to the semiconductor chip, and checking whether the heat-conducting material is separated from the semiconductor chip.

Accordingly, when it is decided that the heat-conducting material is separated from the semiconductor chip in the checking, it is possible to repair the separation by injecting the heat-conducting material from the through hole, to secure excellent bondability of the heat-conducting material to the semiconductor chip, and to secure an excellent heat dissipation property of heat generated in the semiconductor chip.

According to another embodiment of the present application, there is provided an electronic device including a circuit board disposed inside an external housing, and a semiconductor device connected to a predetermined circuit in the circuit board. The semiconductor device includes a wiring board including a plurality of alternately stacked insulating layers and wiring layers, the wiring layers being connected to each other by via-plugs, a semiconductor chip mounted on the wiring board, a heat-dissipating member that is disposed on a side opposite to the wiring board with the semiconductor chip sandwiched between the wiring board and the heat-dissipating member, and dissipates heat generated in the semiconductor chip, a sealing resin layer that is bonded to the wiring board and the heat-dissipating member between the wiring board and the heat-dissipating member, and seals the semiconductor chip from an outer periphery side, and a heat-conducting material that is bonded to the semiconductor chip and the heat-dissipating member between the semiconductor chip and the heat-dissipating member inside the sealing resin layer and conducts heat generated in the semiconductor chip to the heat-dissipating member. A through hole to the heat-conducting material is formed in the heat-dissipating member.

Accordingly, when a warp is generated in the semiconductor device and the heat-conducting material is separated from the semiconductor chip, it is possible to repair the separation by injecting the heat-conducting material from the through hole, to secure excellent bondability of the heat-conducting material to the semiconductor chip, and to secure an excellent heat dissipation property of heat generated in the semiconductor chip.

Additional features and advantages are described herein, and will be apparent from the following Detailed Description and the figures.

### BRIEF DESCRIPTION OF THE FIGURES

FIG. 1 together with FIGS. 2 to 16 illustrate best modes of a semiconductor device, a method for manufacturing the semiconductor device, and an electronic device according to embodiments of the present application, and FIG. 1 is a perspective view of an electronic device;

FIG. 2 is a block diagram illustrating a circuit configuration of the electronic device;

FIG. 3 is a perspective view of a semiconductor device;

FIG. 4 is a cross-sectional view of the semiconductor device;

FIG. 5 is a schematic enlarged cross-sectional view of a wiring board;

FIG. 6 is an enlarged cross-sectional view illustrating portions of a heat-dissipating member and a heat-conducting material;

FIG. 7 is a flow chart illustrating an outline of a method for manufacturing the semiconductor device;

FIG. 8 together with FIGS. 9 to 16 illustrate the method for manufacturing the semiconductor device, and FIG. 8 is a cross-sectional view illustrating a state where a semiconductor chip is mounted on the wiring board;

FIG. 9 is a cross-sectional view illustrating a state in which a space between the wiring board and a semiconductor chip is filled with an underfill resin material;

FIG. 10 is a cross-sectional view illustrating a state in which the wiring board is inserted and disposed in a depression part for disposition in a lower mold and a release film is inserted;

FIG. 11 is a cross-sectional view illustrating a state in which a resin tablet is input to a pot of the lower mold;

FIG. 12 is a cross-sectional view illustrating a state in which a suction mechanism is operated, air is exhausted from suction holes, and the release film adheres to a formation surface of an upper mold;

FIG. 13 is a cross-sectional view illustrating a state in which the upper mold and the lower mold are jointed to each other and mold clamping is performed;

FIG. 14 is a cross-sectional view illustrating a state where a plunger is operated and a melting resin is fluxed to a cavity;

FIG. 15 is a cross-sectional view illustrating a state in which the melting resin with which the cavity is filled is solidified and a sealing resin layer is formed in the periphery of the semiconductor chip;

FIG. 16 is a cross-sectional view illustrating a state where the upper mold and the lower mold are parted from each other and the wiring board is taken out of a mold for formation;

FIG. 17 together with FIG. 18 illustrates a state of a warp generated in a semiconductor device, and FIG. 17 is a cross-sectional view illustrating a state where a wiring board is curved to project downward; and

FIG. 18 is a cross-sectional view illustrating the state where the wiring board is curved to project upward.

### DETAILED DESCRIPTION

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, best modes for implementing a semiconductor device, a method for manufacturing the semiconductor device, and an electronic device according to embodiments of the present application will be described with reference to attached drawings.

A semiconductor device described below is a structure body that is a so-called semiconductor package in which a wiring board, a semiconductor chip, and a heat-dissipating member are sequentially disposed in the thickness direction. As the wiring board, for example, a wiring board called coreless board that does not have a core layer (core board) is used.

In the following description, front, back, up, down, left, and right directions are all referred to by referring to, as the up-down direction, the direction (thickness direction) in which the wiring board, the semiconductor chip, and the heat-dissipating member are disposed.

Note that the front, back, up, down, left, and right directions described below are used for convenience of the description, and the implementation of the present application is not limited to these directions.

[Schematic Structure of Electronic Device]

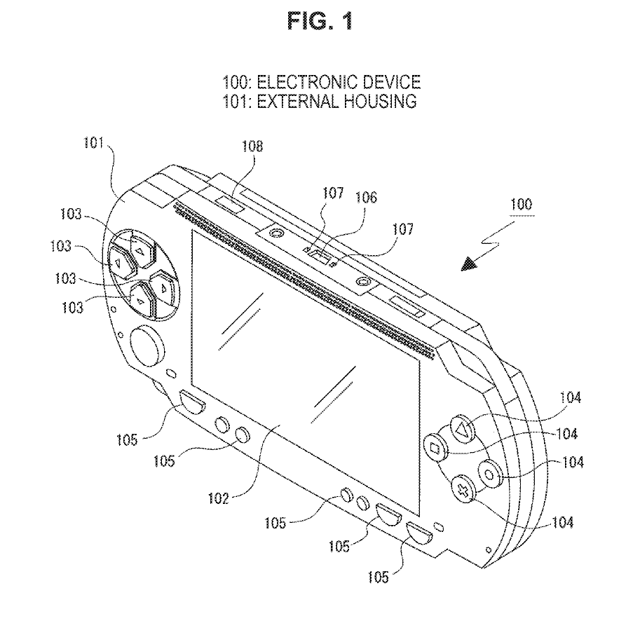

First, a schematic structure of an electronic device 100 will be described (see FIG. 1).

The electronic device 100 is, for example, formed by disposing necessary units inside and outside an external housing 101 formed in an oblong and flat form, and used as a game machine, for example.

On a front surface of the external housing 101, a display panel 102 is provided in a central part in the left-right direction, and operation keys 103, 103, . . . and operation keys 104, 104, . . . are provided in circumferential directions to be separately arranged on the left and the right of the display panel 102. Further, operation keys 105, 105, . . . are provided in a lower end portion of the front surface of the external housing 101.

The operation keys 103, 103, . . . , the operation keys 104, 104, . . . , and the operation keys 105, 105, . . . function as direction keys, decision keys, and the like used to select menu items displayed on the display panel 102 or to play games, for example.

On a top surface of the external housing 101, a connection terminal 106 for connecting an external device, supplement terminals 107 and 107 for supplement of power, a light-receiving window 108 for conducting infrared communication with an external device, and the like are provided.

[Circuit Configuration of Electronic Device]

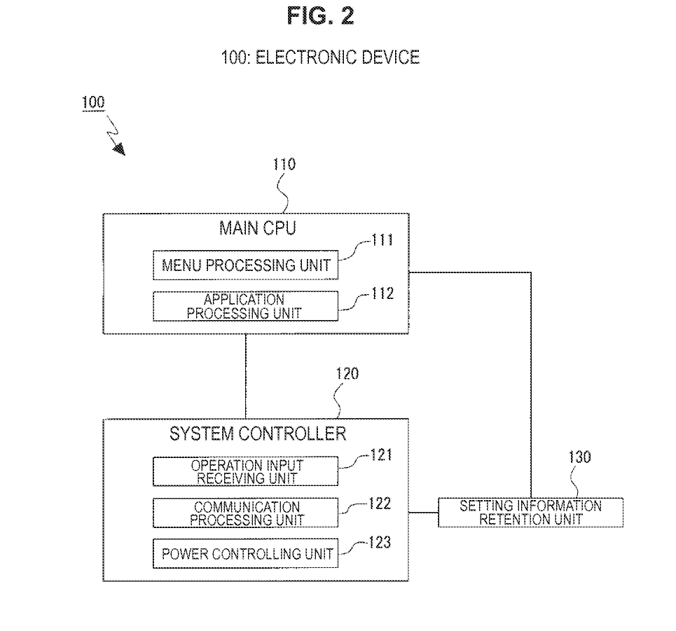

Next, a circuit configuration of the electronic device 100 will be described (see FIG. 2).

The electronic device 100 includes a main CPU (central processing unit) 110 and a system controller 120. Power is supplied to the main CPU 110 and the system controller 120 from an unillustrated battery by a different system, for example.

Further, the electronic device 100 includes a setting information retention unit 130, such as a memory that retains various pieces of information that are set by a user.

The main CPU 110 includes a menu processing unit 111 that generates a menu screen so that a user can set various pieces of information and select applications, and an application processing unit 112 that executes the applications. The set information is transmitted to the setting information retention unit 130 by the main CPU 110 and is retained in the setting information retention unit 130.

The system controller 120 includes an operation input receiving unit 121, a communication processing unit 122, and a power controlling unit 123. The operation input receiving unit 121 checks states of the operation keys 103, 103, . . . , the operation keys 104, 104, . . . , and the operation keys 105, 105, . . . , the communication processing unit 122 performs a communication processing with an external device, and the power controlling unit 123 controls power supplied to each unit.

[Structure of Semiconductor Device]

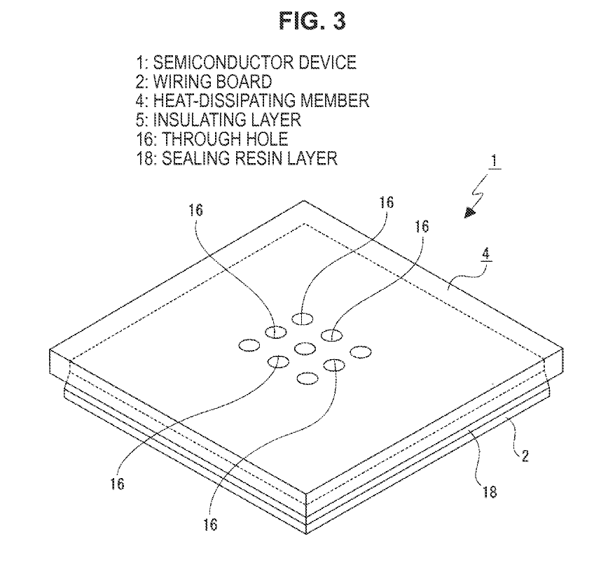

Next, a structure of a semiconductor device 1 will be described (see FIGS. 3 to 6).

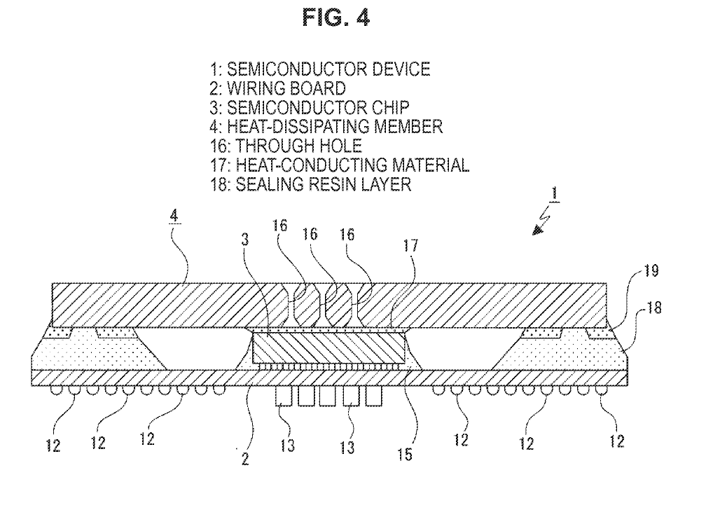

The semiconductor device 1 includes a wiring board 2, a semiconductor chip 3, and a heat-dissipating member 4 (see FIGS. 3 and 4). The semiconductor device 1 has, for example, a BGA (ball grid array) structure in which later-described solder balls are provided in an array form below a lower surface of the wiring board 2.

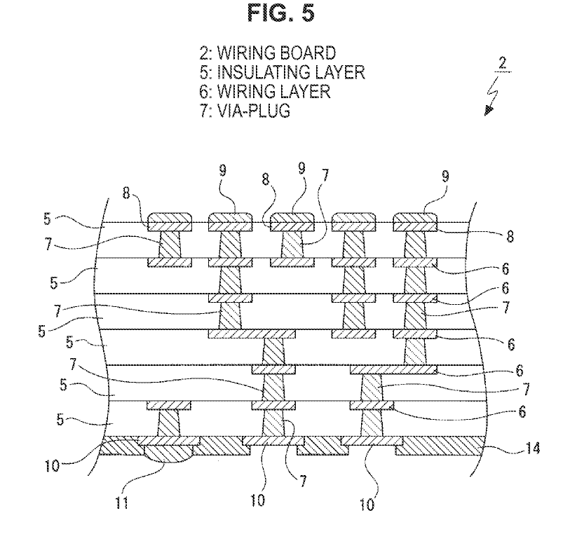

The wiring board 2 is, for example, a coreless board that does not have a core layer, and includes a plurality of insulating layers 5, 5, . . . , and a plurality of wiring layers 6, 6, . . . , which are alternately stacked (see FIG. 5). Examples of a material for the insulating layer 5 include an epoxy resin, and examples of a material for the wiring layer 4 include copper, silver, nickel, and the like. The wiring layers 6, 6, . . . are connected from an upper layer to a lower layer in a predetermined path by via-plugs 7, 7, . . . .

On a top surface of the wiring board 2, that is, a top surface of the uppermost insulating layer 5, connection pads 8, 8, . . . are formed. The connection pads 8, 8, . . . are connected to terminal portions of the semiconductor chip 3. The connection pads 8, 8, . . . are, for example, formed in an array form by electroplating with nickel, lead, gold, or an alloy thereof.

On the connection pads 8, 8, . . . , controlled collapse chip connection (C4) bumps 9, 9, . . . are provided using tin, lead, or an alloy thereof.

Below a lower surface of the wiring board 2, that is, a lower surface of the undermost insulating layer 5, lands 10, 10, . . . are formed. On the lands 10, 10, . . . positioned on a central side of the wiring board 2, electrode pads 11, 11, . . . are formed using tin, silver, copper, or an alloy thereof. The lands 10, 10, . . . are connected to connection terminals of an unillustrated circuit board (motherboard) by solder balls 12, 12, . . . provided in an array form, and the electrode pads 11, 11, . . . are connected to capacitors 13, 13, . . . (see FIG. 4).

The capacitors 13, 13, . . . are connected to the lower surface of the wiring board 2 directly beneath the semiconductor chip 3.

By thus connecting the capacitors 13, 13, . . . to the lower surface of the wiring board 2 directly beneath the semiconductor chip 3, wiring paths from the semiconductor chip 3 to the capacitors 13, 13, . . . are shortened and wiring resistance can be reduced.

Note that positions of the capacitors 13, 13, . . . are not limited to the lower surface of the wiring board 2 directly beneath the semiconductor chip 3, and may be, for example, the lower surface of the wiring board 2 not directly beneath the semiconductor chip 3 as long as the wiring paths are sufficiently shortened. Further, the capacitors 13, 13, . . . may be, for example, connected to a top surface of the wiring board 2 and sealed by the later-described sealing resin layer as long as the wiring paths are sufficiently shortened.

Below the lower surface of the undermost insulating layer 5, solder resists 14 are formed in portions where the lands 10, 10, . . . are not formed (see FIG. 5).

As described above, the wiring substrate 2 is formed as the coreless board that does not have the core layer, and can be thinned to approximately 300 μm with a six layer structure, for example. By reducing the thickness of the wiring board 2, the length of wiring can be reduced, and accordingly, the operation speed of the semiconductor device 1 can be higher.

The semiconductor chip 3 is an LSI (large scale integration) or the like, and external electrodes are bonded to the top surface of the wiring board 2 by flipchip connection (see FIGS. 3 and 4). Specifically, solder bumps serving as the external electrodes of the semiconductor chip 3 are bonded to the C4 bumps 9, 9, . . . of the wiring board 2 by solder.

A space between the wiring board 2 and the semiconductor chip 3 is filled with an underfill resin material 15. By filling the space between the wiring board 2 and the semiconductor chip 3 with the underfill resin material 15, stress on the solder bumps is dispersed, and accordingly, reliability of the semiconductor device 1 is increased.

The heat-dissipating member 4 is formed using a metal material having a high heat dissipation property in a rectangle plate form, for example. In a central portion of the heat-dissipating member 4, for example, through holes 16, 16, . . . each of which penetrates the heat-dissipating member 4 in the up-down direction are formed to be arranged at regular intervals in the front-back and left-right directions.

The thickness of the heat-dissipating member 4 is, for example, 0.5 mm to 2.0 mm, and the diameter of each of the through holes 16 is, for example, approximately 0.3 mm.

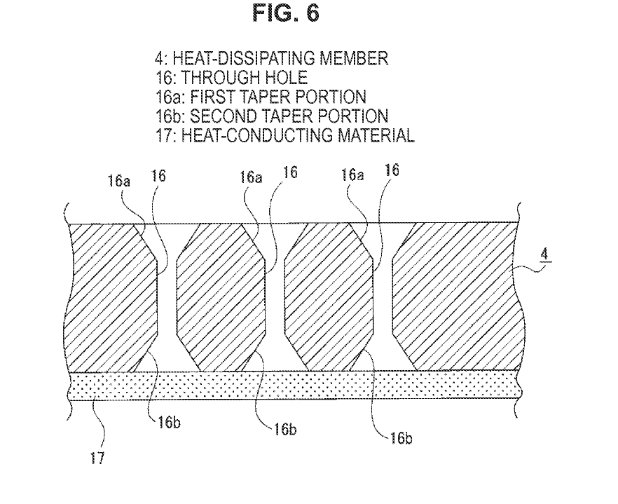

In each of the through holes 16, an upper end portion is formed as a first taper portion 16a in which the diameter becomes larger as the upper end portion is closer to the above, and a lower end portion is formed as a second taper portion 16b in which the diameter becomes larger as the lower end portion is closer to the lower part (see FIG. 6).

The heat-dissipating member 4 is disposed over a top surface of the semiconductor chip 3 with a heat-conducting material 17 interposed therebetween (see FIGS. 3 and 4). The heat-conducting material 17 is provided as a thermal interface material (TIM) using, for example, an alumina paste, a silver past, or the like. A lower surface of the heat-conducting material 17 is bonded to the top surface of the semiconductor chip 3, and a top surface of the heat-conducting material 17 is bonded to a central portion in the lower surface of the heat-dissipating member 4 (see FIG. 4). The heat-conducting material 17 is bonded in the entire region where the through holes 16, 16, . . . in the heat-dissipating member 4 are formed.

In an outer periphery portion of the wiring board 2, that is, on an outer periphery side of the semiconductor chip 3, a sealing resin layer 18 is provided, an outer periphery portion of the heat-dissipating member 4 is bonded to the sealing resin layer 18 with an adhesive resin 19, and the heat-dissipating member 4 is fixed to the wiring board 2. Therefore, the semiconductor chip 3 is sealed from the outer periphery side with the sealing resin layer 18.

Note that the sealing resin layer 18 is desirably provided to outside of the outermost solder balls 12, 12, . . . out of the solder balls 12, 12, . . . provided in an array form.

By providing the sealing resin layer 18 to outside of the outermost solder balls 12, 12, . . . , the strength of the wiring substrate 2 is increased by the sealing resin layer 18, and accordingly, a warp of the wiring board 2 can be suppressed. In this manner, since the sealing resin layer 18 functions as a reinforcement material of the wiring board 2; therefore, even when the wiring board 2 is made thinner, a high strength of the semiconductor device 1 can be secured.

As the adhesive resin 19, it is possible to use a variety of adhesives such as an epoxy-based adhesive and an acrylic-based adhesive, a heat conductor paste such as TIM or silicon grease, and any of a variety of materials such as indium or gold. The adhesive resin 19 can be selected as appropriate considering materials of the sealing resin layer 18 and the heat-dissipating member 4.

Note that a heat sink may be disposed over the top surface of the heat-dissipating member 4. When the heat sink is disposed, heat generated in the semiconductor chip 3 is conducted in the heat-conducting material 17 and is dissipated from the heat-dissipating member 4 and the heat sink.

[Outline of Method for Manufacturing Semiconductor Device]

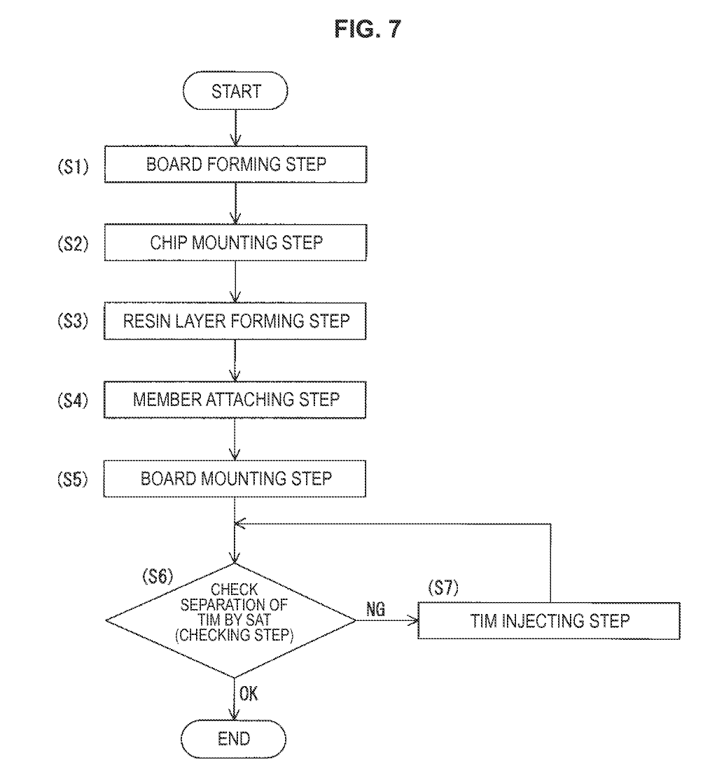

Next, an outline of a method for manufacturing the semiconductor device 1 will be described (see FIG. 7).

(S1) Manufacture of the semiconductor device 1 starts, and the wiring board 2 having a multilayer wiring structure including the plurality of insulating layers 5, 5, . . . and the plurality of wiring layers 6, 6, . . . which are alternately stacked is formed (board forming step).

(S2) Next, the semiconductor chip 3 is mounted on the wiring substrate 2 (chip mounting step). Specifically, the solder bumps serving as the external electrodes of the semiconductor chip 3 are bonded to the C4 bump 9, 9, . . . of the wiring board 2 by solder.

(S3) Consequently, the sealing resin layer 18 is formed over the wiring board 2 in the periphery of the semiconductor chip 3 (resin layer forming step).

(S4) Next, the heat-conducting material 17 is bonded to a top surface of the semiconductor chip 3 and also the adhesive resin 19 is applied onto the sealing resin layer 18, and the heat-dissipating member 4 is attached (member attaching step). The central portion of the heat-dissipating member 4 is bonded to the heat-conducting material 17, and the semiconductor chip 3 is sealed from the outer periphery side with the sealing resin layer 18.

(S5) Next, the solder balls 12, 12, . . . , the capacitors 13, 13, . . . , and the like are formed on the lower surface of the wiring board 2, and the wiring board 2 is connected to the circuit substrate by reflow (board mounting step).

(S6) Next, it is checked whether the heat-conducting material (TIM) 17 is separated from the top surface of the semiconductor chip 3 by a scanning acoustic temograph (SAT) (checking step). When a result of the check decides that the heat-conducting material 17 is separated from the top surface of the semiconductor chip 3, the process moves to the NG side, (S7). On the other hand, when a result of the check decides that the heat-conducting material 17 is not separated from the top surface of the semiconductor chip 3, the process moves to the OK side, and the manufacturing process ends.

(S7) The heat-conducting material 17 is injected from the through holes 16, 16, . . . in the heat-dissipating member 4. By injecting the heat-conducting material 17 from the though holes 16, 16, . . . , the heat-conducting material 17 is bonded again to the top surface of the semiconductor chip 3, and the separation of heat-conducting material 17 from the top surface of the semiconductor chip 3 is repaired.

[Details of Method for Manufacturing Semiconductor Device]

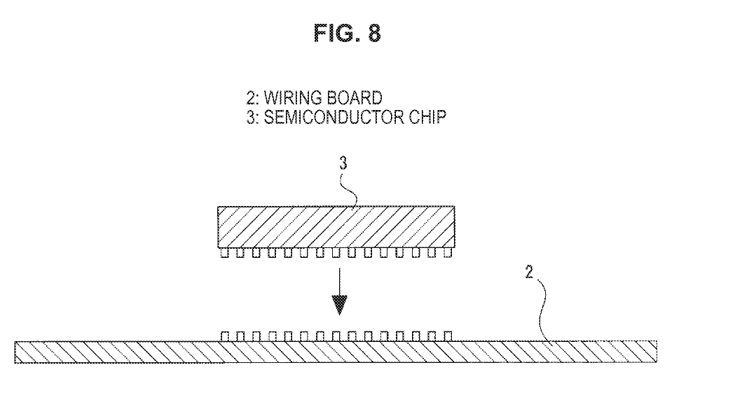

Next, details of the method for manufacturing the semiconductor device 1 will be described (see FIGS. 8 to 16).

Firstly, the wiring board 2 having a multi-layer wiring structure in which the plurality of insulating layers 5, 5, . . . and the plurality of wiring layers 6, 6, . . . are alternately stacked is formed in the board forming step.

Next, the semiconductor chip 3 is flipchip-mounted on the wiring board 2 in a state where the semiconductor chip 3 faces downward (see FIG. 8). Specifically, the solder bumps serving as the external electrodes of the semiconductor chip 3 are bonded to the C4 bumps 9, 9, . . . of the wiring board 2 by solder.

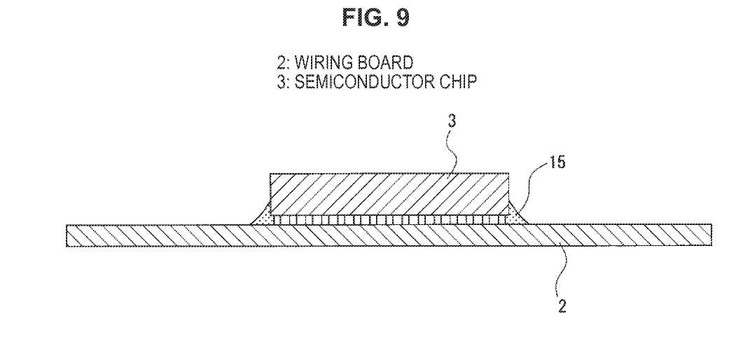

Next, the space between the wiring board 2 and the semiconductor chip 3 is filled with the underfill resin material 15 (see FIG. 9). By filling the space between the wiring board 2 and the semiconductor chip 3 with the underfill resin material 15, the semiconductor chip 3 is mounted on the wiring board 2 in a state where stress generated from a bonding portion by solder is dispersed.

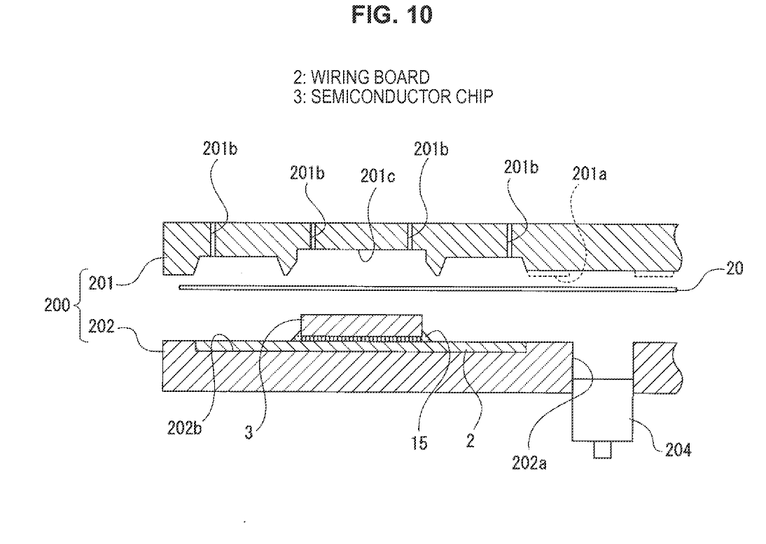

Consequently, the sealing resin layer 18 is formed in the following manner (see FIGS. 10 to 16).

The sealing resin layer 18 is formed by using a mold for formation 200, and the mold for formation 200 includes an upper mold 201 and a lower mold 202 (see FIG. 10). On the upper mold 201, a runner 201a to be a flow path of a melting resin is formed. The runner 201a is a flow path to a cavity 203 formed when the upper mold 201 and the lower mold 202 are jointed to each other.

In the upper mold 201, suction holes 201b, 201b, . . . to a suction mechanism, such as a pump, are formed.

The lower mold 202 includes a pot 202a for pumping of a plunger 204. Further, in the lower mold 202, a depression part for disposition 202b for disposing the wiring board 2 is formed.

In the above mold for formation 200, first, the wiring board 2 on which the semiconductor chip 3 is mounted is inserted and disposed in the depression part for disposition 202b in the lower mold 202 (see FIG. 10).

Next, a release film 20 is inserted between the upper mold 201 and the lower mold 202. The release film 20 is inserted in a position so as to cover the entire wiring board 2.

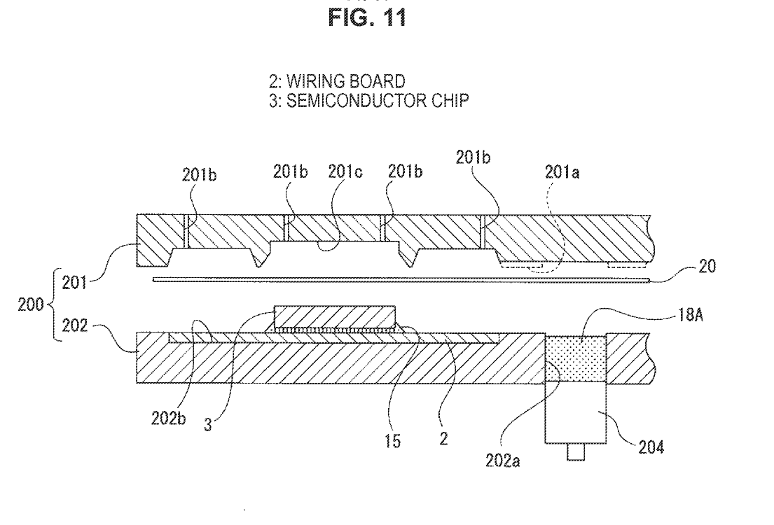

Next, a solid resin tablet 18A is input to the pot 202a in the lower mold 202 (see FIG. 11). The resin tablet 18A is a material for forming the sealing resin layer 18 and is a material that changes into a liquid by being heated.

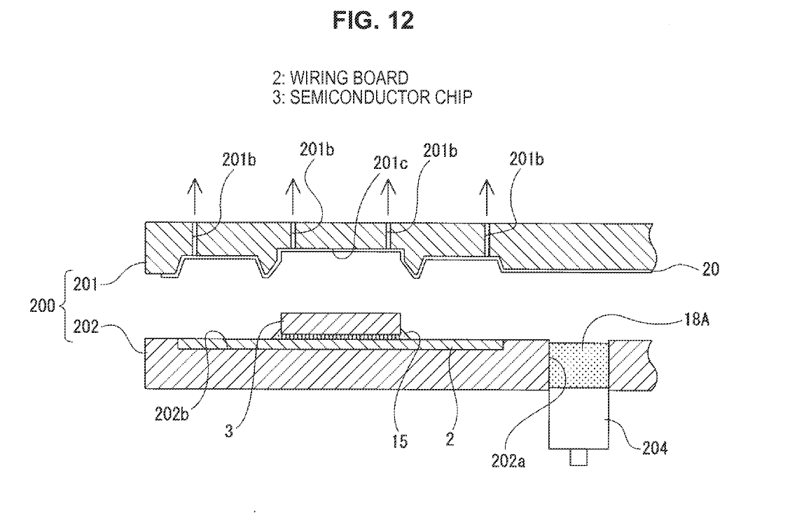

Consequently, the suction mechanism is operated, air between the upper mold 201 and the release film 20 is exhausted from the suction holes 201b, 201b, . . . , and the release film 20 is adhered to a formation surface 201c of the upper mold 201 (see FIG. 12). In this manner, by using the release film 20, the sealing resin layer 18 can be formed without a touch between the formation surface 201c and the later-described melting resin with which the cavity 203 is to be filled later. Therefore, cleaning of the upper mold 201 is unnecessary, and it is possible to increase the productivity and to reduce the manufacturing cost.

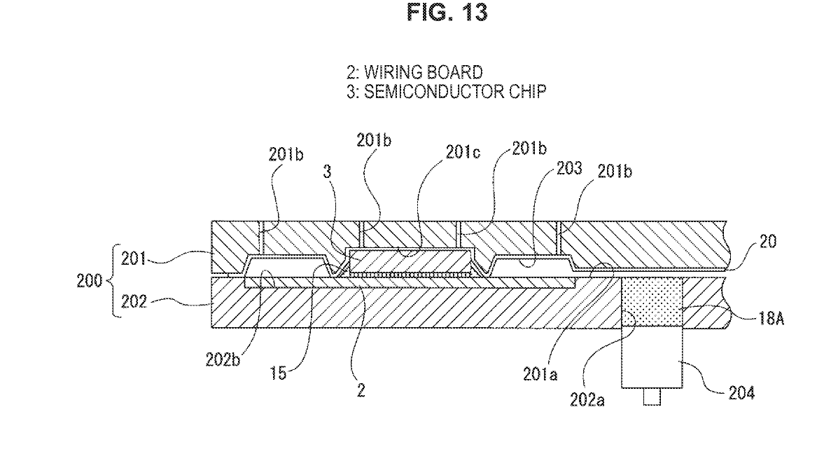

Next, the upper mold 201 and the lower mold 202 are jointed to each other to perform mold clamping (see FIG. 13). By performing the mold clamping, the cavity 203 is formed and also the release film 20 is adhered to the top surface of the semiconductor chip 3.

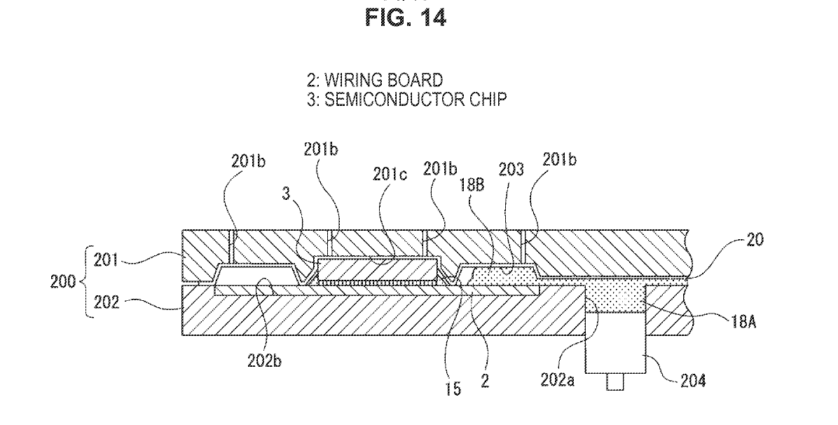

Next, in a state where the resin tablet 18A is heated and melted, the plunger 204 is operated so that the resin tablet 18A is fluxed to the cavity 203 from the runner 201a (see FIG. 14). At this time, the resin tablet 18A changes into a liquid as a melting resin 18B by being heated, and the cavity 203 formed in the periphery of the semiconductor chip 3 is filled with the melting resin 18B.

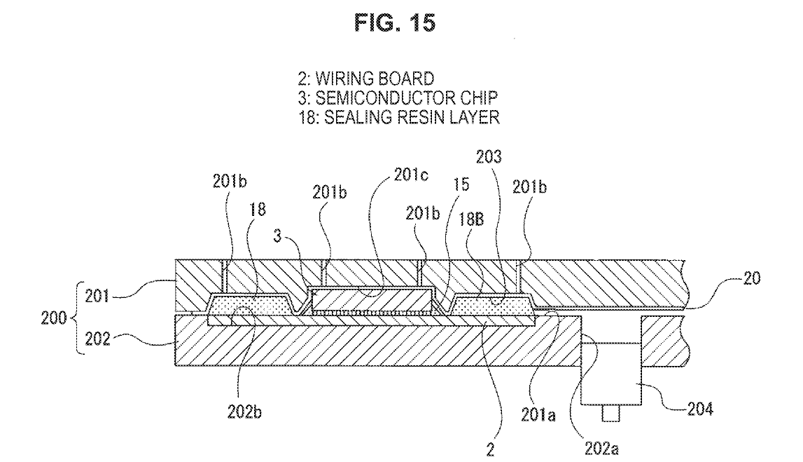

Consequently, by performing heating treatment for a fixed time, the melting resin 18B in the cavity 203 is solidified, and the sealing resin layer 18 is formed in the periphery of the semiconductor chip 3 (see FIG. 15).

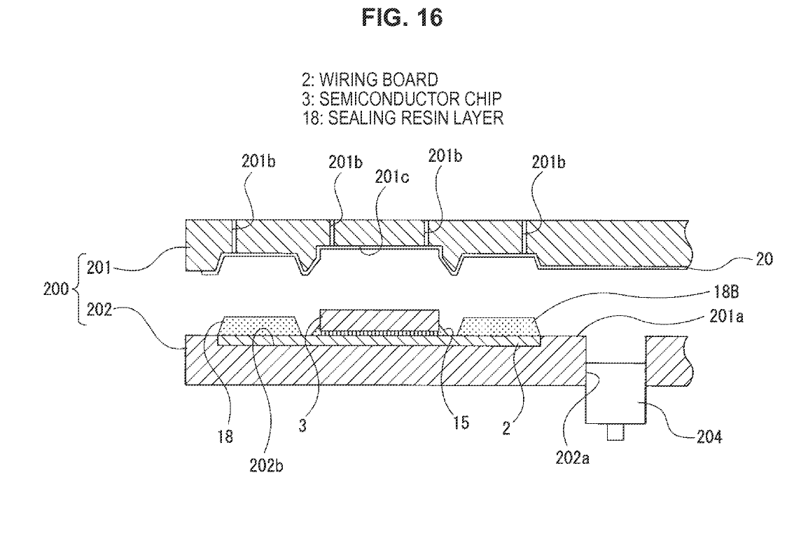

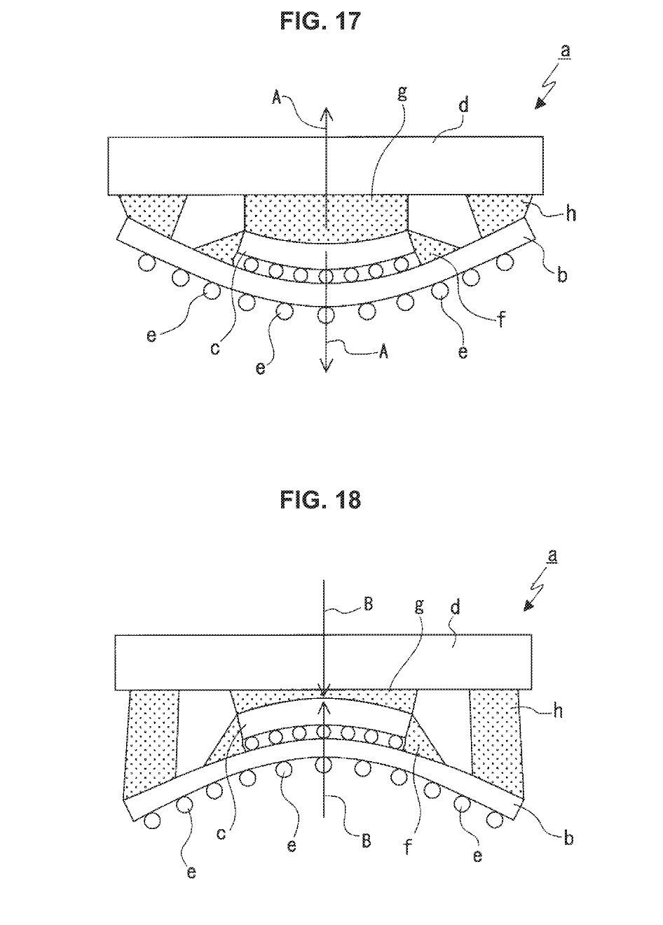

Lastly, the upper mold 201 and the lower mold 202 are parted (see FIG. 16), and the wiring board 2 over which the sealing resin layer 18 is formed is taken out of the mold for formation 200.

### CONCLUSION

As describe above, in the electronic device 100 and the semiconductor device 1, the though holes 16, 16, . . . to the heat-conducting material 17 are formed in the heat-dissipating member 4 that dissipates heat generated in the semiconductor chip 3.

Therefore, when a warp is generated in the semiconductor device 1 and the heat-conducting material 17 is separated from the semiconductor chip 3, it is possible to repair the separation by injecting the heat-conducting material 17 from the though holes 16, 16, . . . , to secure excellent bondability of the heat-conducting material 17 to the semiconductor chip 3, and to secure an excellent heat dissipation property of heat generated in the semiconductor chip 3.

Further, since the terminal portion of the though hole 16 on a side opposite to the heat-conducting material 17 is formed as the first taper portion 16a in which the diameter becomes larger as the terminal portion is farther away from the heat-conducting material 17, the heat-conducting material 17 can be easily injected to the through hole 16, and the efficiency of the injection can be increased.

Furthermore, since the first taper portion 16a is formed in the though hole 16, when the heat sink is disposed over the top surface of the heat-dissipating member 4, the bonding strength of heat-conducting material 17 to the heat sink is increased, excellent conductivity of heat to the heat sink from the heat-conducting material 17 can be secured, and the heat dissipation performance can be increased.

Moreover, since the terminal portion of the though hole 16 on the heat-conducting material 17 side is formed as the second taper portion 16a in which the diameter becomes larger as the terminal portion is closer to the heat-conducting material 17, the bonding strength of heat-conducting material 17 to the heat-dissipating member 4 is increased, excellent conductivity of heat to the heat-dissipating member 4 from the heat-conducting material 17 can be secured, and the heat dissipation performance can be increased.

In addition, in the manufacturing process of the semiconductor device 1, since it is checked whether the heat-conducting material 17 is separated from the semiconductor chip 2, it is reliably decided whether the heat-conducting material 17 is separated from the semiconductor chip 3, and by injecting the heat-conducting material 17 from the though holes 16, 16, . . . only in a case of necessity, the manufacturing efficiency of the semiconductor device 1 can be increased.

[The Present Application]

Additionally, the present application may also be configured as below.

(1) A semiconductor device including:

a wiring board including a plurality of alternately stacked insulating layers and wiring layers, the wiring layers being connected to each other by via-plugs;

a semiconductor chip mounted on the wiring board;

a heat-dissipating member that is disposed on a side opposite to the wiring board with the semiconductor chip sandwiched between the wiring board and the heat-dissipating member, and dissipates heat generated in the semiconductor chip;

a sealing resin layer that is bonded to the wiring board and the heat-dissipating member between the wiring board and the heat-dissipating member, and seals the semiconductor chip from an outer periphery side; and

a heat-conducting material that is bonded to the semiconductor chip and the heat-dissipating member between the semiconductor chip and the heat-dissipating member inside the sealing resin layer and conducts heat generated in the semiconductor chip to the heat-dissipating member,

wherein a through hole to the heat-conducting material is formed in the heat-dissipating member.

(2) The semiconductor device according to (1), wherein a terminal portion of the through hole on a side opposite to the heat-conducting material is formed as a taper portion in which a diameter becomes larger as the terminal portion is farther away from the heat-conducting material.

(3) The semiconductor device according to (1), wherein a terminal portion of the through hole on a heat-conducting material side is formed as a taper portion in which a diameter becomes larger as the terminal portion is closer to the heat-conducting material.

(4) The semiconductor device according to any one of (1) to (3), wherein it is checked whether the heat-conducting material is separated from the semiconductor chip.

(5) A method for manufacturing a semiconductor device, the method including:

forming a wiring board including a plurality of alternately stacked insulating layers and wiring layers, the wiring layers being connected to each other by via-plugs;

mounting a semiconductor chip on the wiring board;

forming a sealing resin layer that is bonded to the wiring board and seals the semiconductor chip from an outer periphery side;

attaching, to the semiconductor chip, a heat-dissipating member including a through hole to a heat-conducting material bonded to the semiconductor chip; and

checking whether the heat-conducting material is separated from the semiconductor chip.

(6) An electronic device including:

a circuit board disposed inside an external housing; and

a semiconductor device connected to a predetermined circuit in the circuit board,

wherein the semiconductor device includes
a wiring board including a plurality of alternately stacked insulating layers and wiring layers, the wiring layers being connected to each other by via-plugs,
a semiconductor chip mounted on the wiring board,
a heat-dissipating member that is disposed on a side opposite to the wiring board with the semiconductor chip sandwiched between the wiring board and the heat-dissipating member, and dissipates heat generated in the semiconductor chip,
a sealing resin layer that is bonded to the wiring board and the heat-dissipating member between the wiring board and the heat-dissipating member, and seals the semiconductor chip from an outer periphery side, and
a heat-conducting material that is bonded to the semiconductor chip and the heat-dissipating member between the semiconductor chip and the heat-dissipating member inside the sealing resin layer and conducts heat generated in the semiconductor chip to the heat-dissipating member,
wherein a through hole to the heat-conducting material is formed in the heat-dissipating member.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A semiconductor device comprising:
a wiring board including a plurality of alternately stacked insulating layers and wiring layers, the wiring layers being connected to each other by via-plugs;
a semiconductor chip mounted on the wiring board;
a heat-dissipating member that is disposed on a side opposite to the wiring board with the semiconductor chip sandwiched between the wiring board and the heat-dissipating member, and dissipates heat generated in the semiconductor chip;
a sealing resin layer that is bonded to the wiring board and the heat-dissipating member between the wiring board and the heat-dissipating member, and seals the semiconductor chip from an outer periphery side; and
a heat-conducting material that is bonded to the semiconductor chip and the heat-dissipating member between the semiconductor chip and the heat-dissipating member inside the sealing resin layer and conducts heat generated in the semiconductor chip to the heat-dissipating member,
wherein a through hole to the heat-conducting material is formed in the heat-dissipating member.

2. The semiconductor device according to claim 1, wherein a terminal portion of the through hole on a side opposite to the heat-conducting material is formed as a taper portion in which a diameter becomes larger as the terminal portion is farther away from the heat-conducting material.

3. The semiconductor device according to claim 1, wherein a terminal portion of the through hole on a heat-conducting material side is formed as a taper portion in which a diameter becomes larger as the terminal portion is closer to the heat-conducting material.

4. The semiconductor device according to claim 1, wherein it is checked whether the heat-conducting material is separated from the semiconductor chip.

5. A method for manufacturing a semiconductor device, the method comprising:
forming a wiring board including a plurality of alternately stacked insulating layers and wiring layers, the wiring layers being connected to each other by via-plugs;
mounting a semiconductor chip on the wiring board;
forming a sealing resin layer that is bonded to the wiring board and seals the semiconductor chip from an outer periphery side;
attaching, to the semiconductor chip, a heat-dissipating member including a through hole to a heat-conducting material bonded to the semiconductor chip; and
checking whether the heat-conducting material is separated from the semiconductor chip.

6. An electronic device comprising:
a circuit board disposed inside an external housing; and
a semiconductor device connected to a predetermined circuit in the circuit board,
wherein the semiconductor device includes
a wiring board including a plurality of alternately stacked insulating layers and wiring layers, the wiring layers being connected to each other by via-plugs,
a semiconductor chip mounted on the wiring board,
a heat-dissipating member that is disposed on a side opposite to the wiring board with the semiconductor chip sandwiched between the wiring board and the heat-dissipating member, and dissipates heat generated in the semiconductor chip,
a sealing resin layer that is bonded to the wiring board and the heat-dissipating member between the wiring board and the heat-dissipating member, and seals the semiconductor chip from an outer periphery side, and
a heat-conducting material that is bonded to the semiconductor chip and the heat-dissipating member between the semiconductor chip and the heat-dissipating member inside the sealing resin layer and conducts heat generated in the semiconductor chip to the heat-dissipating member,
wherein a through hole to the heat-conducting material is formed in the heat-dissipating member.
